(19) United States
(12) Patent Application Publication
(10) Pub. No.: US 2013/0192654 A1
(43) Pub. Date: Aug. 1, 2013

(54) THERMOELECTRIC MODULE COMPRISING THERMOELECTRIC ELEMENT DOPED WITH NANOPARTICLES AND MANUFACTURING METHOD OF THE SAME

(71) Applicant: Jong Bae Shin, Seoul (KR)

(72) Inventor: Jong Bae Shin, Seoul (KR)

(73) Assignee: LG INNOTEK CO., LTD., Seoul (KR)

(21) Appl. No.: 13/819,206

(22) PCT Filed: Jun. 30, 2011
(86) PCT No.: PCT/KR2011/004793

§ 371 Date: Mar. 22, 2013

(30) Foreign Application Priority Data
Aug. 26, 2010 (KR) 10-2010-0082765

(51) Int. Cl. H01L 35/34; H01L 35/28

(52) U.S. Cl. CPC H01L 35/34; H01L 35/28; Y10S 977/773; B82Y 40/00
USPC 136/203; 438/54; 977/773

(57) ABSTRACT

A thermoelectric module and a method of manufacturing the same are provided. The thermoelectric module includes a plurality of thermoelectric elements disposed between first and second substrates opposite to each other and including a metal electrode, the plurality of thermoelectric elements are formed by alternately arranging n-type and p-type thermoelectric semiconductor elements doped with nano particles, and the thermoelectric module includes a thermoelectric element doped with nano particles and connected in series through a metal electrode of upper and lower insulating substrates. Thereby, a thermoelectric index can increase without a high production cost and thus a thermoelectric module having excellent efficiency can be manufactured.

### TECHNICAL FIELD

This application claims priority to Korean Patent Application No. 10-2010-0082765 filed on Aug. 26, 2010, all of which are hereby incorporated by reference in its entirety into this application.

The present invention relates to a structure of thermoelectric module for heat transfer and a method of manufacturing the same.

### BACKGROUND ART

A thermoelectric phenomenon is a phenomenon in which heat emission and cooling occurs (Peltier effect) at both ends of a material bonding portion by applying a current between two materials or in which an electromotive force occurs (seebeck effect) by a temperature difference between two materials, and a thermoelectric element is a metal or a ceramic element having a function of directly converting a heat to electricity or electricity to a heat. By using such a seebeck effect, a heat generating in a computer or a vehicle engine can be converted to electrical energy, and by using a Peltier effect, various cooling systems that do not require a refrigerant can be embodied. Interest has increased in new energy development, waste energy recovery, and environment protection and thus interest in a thermoelectric element has also increased.

In the 1950s, since a Bi-Te-based thermoelectric element was developed, a thermo-electric performance index representing energy conversion efficiency of a thermo-electric material has shown a value of 1 or less at a normal temperature, and maximum cooling efficiency that can obtain through the thermoelectric performance index is about 8% and thus it was limited to use the thermoelectric element for various electronic devices, but in the 2000s, as a nano material and process technology such as a super lattice structure or a quantum confinement effect are added to the thermo-electric element, a thermoelectric performance index remarkably improves and until now, a thermoelectric element having a thermoelectric performance index of 2.4 as a highest value has been reported.

Further, by manufacturing a thermoelectric material in a nano structure having a length unit corresponding to a characteristic wavelength from a wavelength of phonon that charges heat transfer within a material and an average free path of electrons (or holes) that charge electricity transmission, an electron energy level density is controlled, the constant and conductivity of a relative large value are obtained, and a seebeck value of a thermoelectric performance index is improved, or by scattering phonon that charges heat transfer, thermal conductivity is suppressed, and by adjusting an energy band gap, a thermoelectric performance index is remarkably improved with a method of sustaining electrical conductivity.

Efficiency of the thermoelectric element can be generally evaluated with a thermo-electric index represented by the following Equation, and as a thermoelectric index increases, a generating potential difference increases and thus an excellent characteristic is represented.

ZT=(S²σ/k)T

In the Equation, a ZT coefficient is proportional to a seebeck coefficient S and electrical conductivity a of a thermoelectric material and is inversely proportional to thermal conductivity k. Here, a seebeck coefficient represents a magnitude (dV/dT) of a voltage generated according to a unit temperature change. Therefore, in the Equation, in order to apply a ZT coefficient to a thermoelectric element, it is preferable that a thermoelectric material has a large seebeck coefficient and large electric conductivity and small thermal conductivity, but because a seebeck coefficient, electrical conductivity, and thermal conductivity are not independent variables, it is not easy to embody a thermoelectric element having a large ZT coefficient, i.e., excellent efficiency.

In a conventional thermoelectric element cooling method, a thermoelectric element is mainly manufactured in a bulk type, and it has been actively researched to manufacture a thermoelectric element in a nano type, as described above. The reason of changing a manufacturing method from a bulk type to a nano type is that the bulk type has a low thermoelectric index ZT and thus manufactures only a thermoelectric element having low efficiency, as shown in FIG. 1. When a nano element of high efficiency is manufactured, a production cost sharply increases.

### DISCLOSURE OF INVENTION

### Technical Problem

The present invention has been made in view of the above problems, and provides a thermoelectric module and a method of manufacturing the same that have a thermoelectric index value larger than that of an existing bulk type thermoelectric element without a high manufacturing cost by doping a bulk type thermoelectric element with nano particles and recoupling them and thus by blocking a path of phonon.

### Solution to Problem

In accordance with an aspect of the present invention, a thermoelectric module including a thermoelectric element doped with nano particles, the thermoelectric module including: first and second substrates including a metal electrode and disposed opposite to each other; and a plurality of thermoelectric elements disposed between the first and second substrates, wherein the thermoelectric elements are doped with nano particles.

The plurality of thermoelectric elements may be formed in a structure in which n-type thermoelectric semiconductor elements and p-type thermoelectric semiconductor elements doped with nano particles are alternately disposed.

The plurality of thermoelectric elements may be disposed in a structure connected in series through an electrode pattern formed at the other surface of the first and second insulating substrates.

The n-type and p-type thermoelectric semiconductor elements doped with nano particles may include a phonon scattering film formed at a predetermined gap. In this case, the phonon scattering film may have a thickness of 1 nm to 100 nm, and the phonon scattering film may be formed at a gap of 0.01 mm to 0.1 mm.

The phonon scattering film may be formed with one of antimony (Sb), selenium (Se), boron (B), gallium (Ga), and indium (In).

The nano particle may have a particle diameter of 1 nm to 100 nm. Particularly, in this case, the nano particle may be formed with one of antimony (Sb), selenium (Se), boron (B), gallium (Ga), and indium (In).

The thermoelectric module may include a diffusion preventing film formed between the metal electrode and the thermoelectric element.

The diffusion preventing film may be formed with at least one of Pb, Sn, Pt, and Ni.

The first and second substrates may be formed using one of a silicon substrate, aluminum, aluminum nitride (AlN), aluminum oxide (AlOₓ), photo sensitive glass (PSG), BeO, a printed circuit board (PCB), and alumina (Al₂O₃).

A thermoelectric module according to the present invention can be manufactured through the following process.

In accordance with another aspect of the present invention, a method of manufacturing a thermoelectric module including a thermoelectric element doped with nano particles, the method includes: forming a plurality of n-type and p-type thermoelectric semiconductor elements doped with nano particles; and electrically connecting the plurality of n-type and p-type thermoelectric semiconductor elements by alternately arranging the plurality of n-type and p-type thermoelectric semiconductor elements between first and second substrates in which a metal electrode is formed.

The forming of a plurality of n-type and p-type thermoelectric semiconductor elements may include: doping the plurality of n-type and p-type thermoelectric semiconductor elements with nano particles; forming a phonon scattering film at one end of the plurality of n-type and p-type thermoelectric semiconductor elements doped with the nano particles; and forming a plurality of bonded n-type and p-type thermoelectric semiconductor elements by bonding each of n-type and p-type thermoelectric semiconductor elements in which the phonon scattering film is formed.

The doping of the plurality of n-type and p-type thermoelectric semiconductor elements with nano particles may include doping n-type and p-type thermoelectric semiconductor elements having a thickness of 0.01 mm to 0.1 mm with nano particles having a particle diameter of 1 nm to 100 nm.

The doping of the plurality of n-type and p-type thermoelectric semiconductor elements with nano particles may include doping with nano particles formed with one of antimony (Sb), selenium (Se), boron (B), gallium (Ga), and indium (In).

The forming of a phonon scattering film may include forming a phonon scattering film having a thickness of 1 nm to 100 nm.

The forming of a phonon scattering film may include forming a phonon scattering film formed with one of antimony (Sb), selenium (Se), boron (B), gallium (Ga), and indium (In).

The method may further comprise forming a diffusion preventing film at both ends of the plurality of n-type and p-type thermoelectric semiconductor elements, after forming a plurality of n-type and p-type thermoelectric semiconductor elements doped with the nano particles.

### Advantageous Effects of Invention

According to the present invention, in order to prevent movement of phonon that charges movement of a heat in a plurality of bulk type thermoelectric semiconductors, by depositing a phonon scattering film for scattering phonon and recoupling them while doping with nano particles, a path of the phonon is blocked and thus a thermoelectric module including a thermoelectric element having a higher thermal index than that of an existing bulk type thermoelectric element can be embodied.

### BRIEF DESCRIPTION OF DRAWINGS

FIG. 1 is a graph of comparing a bulk type thermoelectric index and a nano type thermoelectric index;

FIG. 2 is a cross-sectional view illustrating a thermoelectric module including a thermoelectric element doped with nano particles according to an exemplary embodiment of the present invention; and

FIG. 3 is a diagram illustrating a process of manufacturing a thermoelectric module including a thermoelectric element doped with nano particles according to an exemplary embodiment of the present invention.

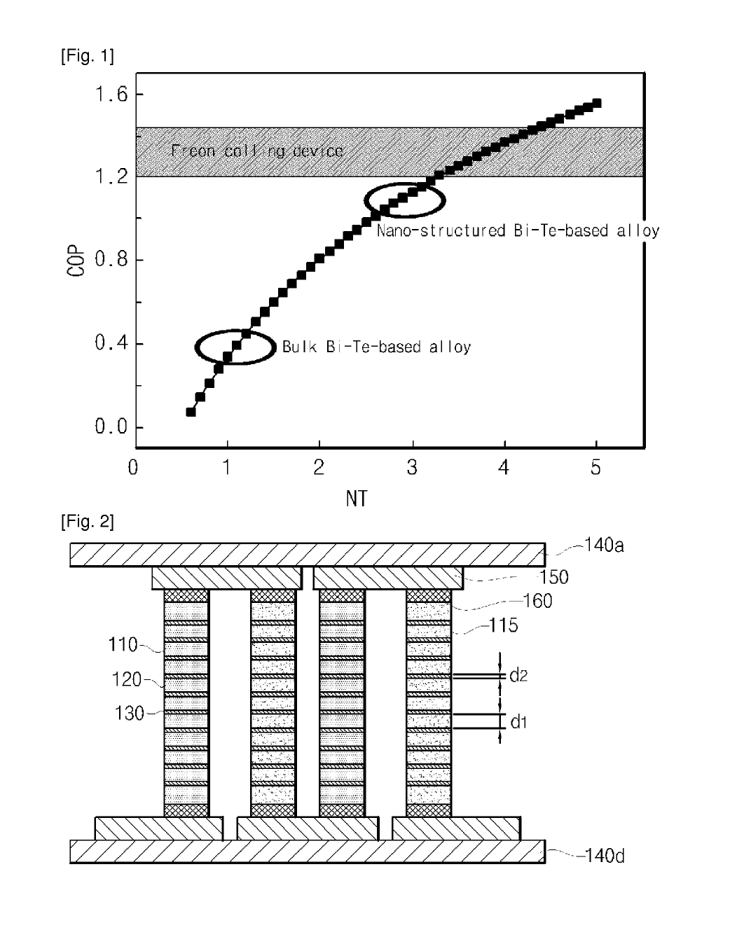

### DESCRIPTION OF REFERENCE NUMERALS INDICATING PRIMARY ELEMENTS IN THE DRAWINGS

110, 115: n-type thermoelectric semiconductor element, p-type thermoelectric semiconductor element

120: nano particle

130: phonon scattering film

140a, 140b: first substrate, second substrate

150: metal electrode

160: diffusion preventing film

### BEST MODE FOR CARRYING OUT THE INVENTION

The present invention relates to a thermoelectric module including a thermoelectric element doped with nano particles and a method of manufacturing the same, and more particularly, to a thermoelectric module and a method of manufacturing the same that can have a higher thermoelectric index value by doping nano particles on several bulk type base members and recoupling them and thus by blocking a path of phonon.

In accordance with an aspect of the present invention, a thermoelectric module including a thermoelectric element doped with nano particles includes: first and second substrates including a metal electrode and disposed opposite to each other; and a plurality of thermoelectric elements disposed between the first and second substrates, wherein the thermoelectric elements are doped with nano particles.

In accordance with another aspect of the present invention, a method of manufacturing a thermoelectric module including a thermoelectric element doped with nano particles, the method includes: forming a plurality of n-type and p-type thermoelectric semiconductor elements doped with nano particles; and electrically connecting the plurality of n-type and p-type thermoelectric semiconductor elements by alternately arranging the plurality of n-type and p-type thermoelectric semiconductor elements between first and second substrates in which a metal electrode is formed.

### Mode for the Invention

Hereinafter, a configuration and function according to an exemplary embodiment of the present invention will be described in detail with reference to the attached drawings. When describing a detailed description with reference to the attached drawings, like reference numerals in the drawings denote like elements. Terms such as a first and a second are used for describing various elements, but the elements are not limited by the terms. The terms are used for distinguishing one element from other elements.

FIG. 2 is a cross-sectional view illustrating a thermoelectric module including a thermoelectric element doped with nano particles according to an exemplary embodiment of the present invention.

Referring to FIG. 2, a thermoelectric module including a thermoelectric element doped with nano particles according to an exemplary embodiment of the present invention includes a metal electrode 150 and a first substrate 140a and a second substrate 140b disposed opposite to each other, and a plurality of thermoelectric elements 110 and 115 are disposed between the first substrate and the second substrate. Particularly, it is preferable that the thermoelectric elements are doped with nano particles.

It is preferable that the first substrate 140a and the second substrate 140b are ceramic substrates and are formed with alumina (Al₂O₃), but are not limited thereto and can be formed using one of a silicon substrate, aluminum, aluminum nitride (AlN), aluminum oxide (AlOₓ), photo sensitive glass (PSG), Al₂O₃, BeO, and a PCB.

The thermoelectric elements are disposed in a structure disposed in parallel between the first substrate 140a and the second substrate 140b, specifically, in a pillar structure in which at least one thermoelectric element supports the first substrate 140a and the second substrate 140b, and more preferably, the thermoelectric elements are separately disposed at a predetermined gap, and in this case, at each thermoelectric element, n-type and p-type thermoelectric semiconductor elements 110 and 115 are alternately disposed. Particularly, in this case, it is more preferable that a plurality of nano particles 120 are doped within the n-type and p-type thermoelectric semiconductor elements 110 and 115.

Therefore, in each thermoelectric element, i.e., in thermoelectric elements doped with a plurality of nano particles 120, a plurality of n-type and p-type thermoelectric semiconductor elements 110 and 115 doped with nano particles are alternately and separately arranged, and the thermoelectric semiconductor elements 110 and 115 are electrically connected in series by the metal electrode 150 and are disposed in parallel.

In this case, it is preferable that the nano particles 120 have a particle diameter of 1 nm to 100 nm and are formed with one of antimony (Sb), selenium (Se), boron (B), gallium (Ga), and indium (In). In this way, because phonon that charges movement of heat can be prevented from moving through the nano particles 120, a thermoelectric index increases, and thus efficiency increases.

Further, the n-type and p-type thermoelectric semiconductor elements 110 and 115 doped with the nano particles 120 may include a phonon scattering film 130 formed at a predetermined gap in order to scatter phonon.

In this case, it is preferable that the phonon scattering film 130 has a thickness d2 of 1 nm to 100 nm and is formed with one of antimony (Sb), selenium (Se), boron (B), gallium (Ga), and indium (In).

Further, it is preferable that the phonon scattering film 130 is formed at a gap d1 of 0.01 mm to 0.1 mm. The phonon scattering film 130 is deposited at one end of a plurality of thermoelectric semiconductor elements 110 and and then by bonding a plurality of thermoelectric semiconductor elements 110 and 115 in which the phonon scattering film 130 is formed, a thermoelectric semiconductor element arranged in a thermoelectric module is formed, and this will be described in detail in the following manufacturing process.

Further, a diffusion preventing film 160 for preventing a metal from being diffused may be formed between the metal electrode 150 and the thermoelectric semiconductor element, and the diffusion preventing film 160 is preferably formed with nickel (Ni). Alternatively, the diffusion preventing film may be formed with at least one of Pb, Sn, Pt, and Ni.

Table 1 illustrates thermoelectric indexes ZT and production costs of an existing bulk type thermoelectric element, a thermoelectric element doped with only nano particles, a thermoelectric element doped with nano particles and in which a phonon scattering film is formed, and a super lattice thermoelectric element.

TABLE 1

| | Bulk type | Thermoelectric | Thermoelectric element doped with | Super lattice |
|---|---|---|---|---|
| | thermoelectric | element doped with | nano particles and in which | thermoelectric |
| | element | nano particles | phonon scattering film is formed | element |
| ZT | 1.0 | 1.5 | 1.75 | 2.5 |
| Cost | 5-200 | 100-1,000 | 100-500 | 5,000 |
| (USD) | | | | |

As can be seen in Table 1, when a thermoelectric performance index of an existing bulk type thermoelectric element is 1.0, a thermoelectric element doped with the nano particles 120 has a performance further improved by 50% than a thermoelectric element in which only an existing bulk material is used, and a thermoelectric element doped with nano particles and in which a phonon scattering film 130 is formed has a performance further improved by 75% than a thermoelectric element in which only an existing bulk material is used. When forming nano particles, a bulk has a thin thickness, compared with an existing method, and thus particles can be relatively easily formed, and a super lattice thermoelectric element that cannot be formed in a large area and that requires a high production cost cannot be used, and an effect for preventing phonon from moving can be maximized.

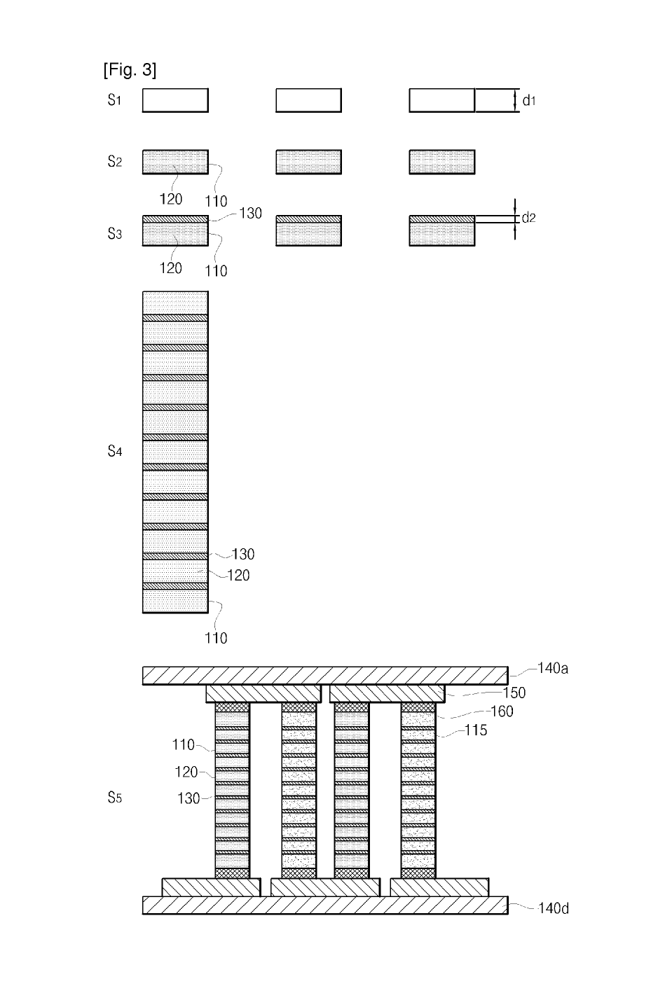

FIG. 3 is a diagram illustrating a process of manufacturing a thermoelectric module including a thermoelectric element doped with nano particles according to an exemplary embodiment of the present invention.

Referring to FIG. 3, a plurality of n-type and p-type thermoelectric semiconductor elements 110 having a thickness d1 0.01 mm to 0.1 mm smaller than a thickness 1 mm to 2 mm of an existing bulk type thermoelectric semiconductor element are manufactured (Si), and the thermoelectric semiconductor element is made of a bismuth telluride (BiTe)-based material. Thereafter, in order to prevent movement of phonon that charges movement of a heat, the nano particles 120 are formed in the plurality of thermoelectric semiconductor elements 110 (S2). In this case, it is preferable that the nano particle 120 has a particle diameter of 1 to 100 nm and is made of one of antimony (Sb), selenium (Se), boron (B), gallium (Ga), and indium (In).

Next, at one end of the thermoelectric semiconductor element 110 doped with the nano particles 120, the phonon scattering film 130 for scattering phonon is coated or deposited (S3), and it is preferable that the phonon scattering film 130 has a thickness of 1 nm to 100 nm and is made of one of antimony (Sb), selenium (Se), boron (B), gallium (Ga), and indium (In), similarly to the nano particle 120.

By bonding in a line the thermoelectric semiconductor elements 110 in which the phonon scattering film 130 is formed, a thermoelectric semiconductor element to be arranged in a thermoelectric module is formed (S4), and the n-type and p-type thermoelectric semiconductor elements are alternately arranged between the first substrate 140a and the second substrate 140b such as alumina in which the metal electrode 150 is formed, but the n-type and p-type thermoelectric semiconductor elements are electrically connected in series through the metal electrode 150 (S5). In this case, in order to prevent a metal from being diffused before connecting the thermoelectric semiconductor elements 110 and 115 and the metal electrode 150, it is preferable to form the diffusion preventing film 160 at both ends of the thermoelectric semiconductor element, and in this case, the diffusion preventing film 160 is preferably formed with nickel (Ni). In this way, by preventing phonon from moving through the nano particles 120 and the phonon scattering film 130, a thermoelectric index increases without a high production cost and thus a thermoelectric module having excellent efficiency can be manufactured.

Although exemplary embodiments of the present invention have been described in detail hereinabove, it should be clearly understood that many variations and modifications of the basic inventive concepts herein described, which may appear to those skilled in the art, will still fall within the spirit and scope of the exemplary embodiments of the present invention as defined in the appended claims.

1. A thermoelectric module comprising a thermoelectric element doped with nano particles, the thermoelectric module comprising:
first and second substrates comprising a metal electrode and disposed opposite to each other; and
a plurality of thermoelectric elements disposed between the first and second substrates, wherein the thermoelectric elements are doped with nano particles.

2. The thermoelectric module of claim 1, wherein the plurality of thermoelectric elements are formed in a structure in which n-type thermoelectric semiconductor elements and p-type thermoelectric semiconductor elements doped with nano particles are alternately disposed.

3. The thermoelectric module of claim 2, wherein the plurality of thermoelectric elements are disposed in a structure connected in series through an electrode pattern formed at the other surface of the first and second substrates.

4. The thermoelectric module of claim 3, wherein the n-type and p-type thermoelectric semiconductor elements doped with nano particles comprise a phonon scattering film formed at a predetermined gap.

5. The thermoelectric module of claim 4, wherein the phonon scattering film has a thickness of 1 nm to 100 nm.

6. The thermoelectric module of claim 4, wherein the phonon scattering film is formed at a gap of 0.01 mm to 0.1 mm.

7. The thermoelectric module of claim 4, wherein the phonon scattering film is formed with one of antimony (Sb), selenium (Se), boron (B), gallium (Ga), and indium (In).

8. The thermoelectric module of claim 3, wherein the nano particle has a particle diameter of 1 nm to 100 nm.

9. The thermoelectric module of claim 8, wherein the nano particle is formed with one of antimony (Sb), selenium (Se), boron (B), gallium (Ga), and indium (In).

10. The thermoelectric module of claim 3, wherein the thermoelectric module comprises a diffusion preventing film formed between the metal electrode and the thermoelectric element.

11. The thermoelectric module of claim 10, wherein the diffusion preventing film is formed with at least one of Pb, Sn, Pt, and Ni.

12. The thermoelectric module of claim 11, wherein the first and second substrates are formed using one of a silicon substrate, aluminum, aluminum nitride (AlN), aluminum oxide (AlOₓ), photo sensitive glass (PSG), BeO, a printed circuit board (PCB), and alumina (Al₂O₃).

13. A method of manufacturing a thermoelectric module comprising a thermoelectric element doped with nano particles, the method comprising:
forming a plurality of n-type and p-type thermoelectric semiconductor elements doped with nano particles; and
electrically connecting the plurality of n-type and p-type thermoelectric semiconductor elements by alternately arranging the plurality of n-type and p-type thermoelectric semiconductor elements between first and second substrates in which a metal electrode is formed.

14. The method of claim 13, wherein the forming of a plurality of n-type and p-type thermoelectric semiconductor elements comprises:
doping the plurality of n-type and p-type thermoelectric semiconductor elements with nano particles;
forming a phonon scattering film at one end of the plurality of n-type and p-type thermoelectric semiconductor elements doped with the nano particles; and
forming a plurality of bonded n-type and p-type thermoelectric semiconductor elements by bonding each of n-type and p-type thermoelectric semiconductor elements in which the phonon scattering film is formed.

15. The method of claim 14, wherein the doping of the plurality of n-type and p-type thermoelectric semiconductor elements with the nano particles comprises doping n-type and p-type thermoelectric semiconductor elements having a thickness of 0.01 mm to 0.1 mm with nano particles having a particle diameter of 1 nm to 100 nm.

16. The method of claim 14, wherein the doping of the plurality of n-type and p-type thermoelectric semiconductor elements with the nano particles comprises doping with nano particles formed with one of antimony (Sb), selenium (Se), boron (B), gallium (Ga), and indium (In).

17. The method of claim 14, wherein the forming of a phonon scattering film comprises forming a phonon scattering film having a thickness of 1 nm to 100 nm.

18. The method of claim 14, wherein the forming of a phonon scattering film comprises forming a phonon scattering film formed with one of antimony (Sb), selenium (Se), boron (B), gallium (Ga), and indium (In).

19. The method of claim 13, after forming a plurality of n-type and p-type thermoelectric semiconductor elements doped with the nano particles and then further comprising forming a diffusion preventing film at both ends of the plurality of n-type and p-type thermoelectric semiconductor elements.

20. The thermoelectric module of claim 4, wherein the nano particle has a particle diameter of 1 nm to 100 nm.

21. The thermoelectric module of claim 20, wherein the nano particle is formed with one of antimony (Sb), selenium (Se), boron (B), gallium (Ga), and indium (In).

22. The thermoelectric module of claim 4, wherein the thermoelectric module comprises a diffusion preventing film formed between the metal electrode and the thermoelectric element.

23. The thermoelectric module of claim 22, wherein the diffusion preventing film is formed with at least one of Pb, Sn, Pt, and Ni.

24. The thermoelectric module of claim 23, wherein the first and second substrates are formed using one of a silicon substrate, aluminum, aluminum nitride (AlN), aluminum oxide (AlOₓ), photo sensitive glass (PSG), BeO, a printed circuit board (PCB), and alumina (Al₂O₃).
